(19) United States
(12) Patent Application Publication
(10) Pub. No.: US 2005/0077553 A1
(43) Pub. Date: Apr. 14, 2005

(54) Methods of forming multi fin FETs using sacrificial fins and devices so formed

(76) Inventors: Sung-min Kim, Incheon-si (KR); Chang-sub Lee, Gyeonggi-do (KR); Jeong-dong Choe, Gyeonggi-do (KR); Hye-jin Cho, Gyeonggi-do (KR); Eun-Jung Yun, Seoul (KR); Shin-ae Lee, Gyeonggi-do (KR)

Correspondence Address: MYERS BIGEL SIBLEY & SAJOVEC, PO BOX 37428, RALEIGH, NC, 27627, US

(21) Appl. No.: 10/947,505

(22) Filed: Sep. 22, 2004

(30) Foreign Application Priority Data
Oct. 14, 2003 (KR) 10-2003-0071439

(51) Int. Cl. H01L 21/336; H01L 21/8234; H01L 29/76; H01L 31/062

(52) U.S. Cl. 257/288; 438/197; 438/268; 257/328

(57) ABSTRACT

Methods of forming multi fin Field Effect Transistors (FET) can include forming a first fin having opposing sidewalls protruding from a substrate and epitaxially growing second fins on the opposing sidewalls, where the second fins have respective exposed sidewalls protruding from the substrate. The second fins or the first fin can be removed to provide at least one fin for a multi fin FET.

### CROSS-REFERENCE TO RELATED APPLICATION

This application claims the benefit of Korean Patent Application No. 2003-71439, filed Oct. 14, 2003, the disclosure of which is hereby incorporated herein by reference in its entirety.

### FIELD OF THE INVENTION

The invention relates to Field Effect Transistors (FETs), and more particularly, to methods of forming fin FETs and devices so formed.

### BACKGROUND

Field effect transistors (FETs) are widely employed in integrated circuits, as FETs may exhibit relatively low power consumption and relatively high integration density compared to bipolar transistors. As is known to those skilled in the art, FETs have a source region and drain region that are spaced apart from each other and a gate electrode located over a channel located between the source and drain regions.

The operating speed of the FETs can be influenced by an “on” current that flows through the channel region. In general, many FETs are planar transistors that include a planar channel. As is well known in the art, the “on” current of the planar transistors can be proportional to the channel width of the FET, e.g., the gate width, and may be inversely proportional to the channel length or distance between the source and drain regions, e.g., the gate length. Moreover, it is known that the operating speed of a FET may be increased by increasing the “on” current by, for example, decreasing the gate length and increasing the gate width.

Increasing the gate width may reduce the effective density of integrated circuits that can be formed in the device. Also, decreasing the gate length may cause short channel effects due to punch-through phenomenon. While the short channel effects may be reduced by increasing the concentration of impurities in the semiconductor substrate, the increase may also lead to increased parasitic capacitance (junction capacitance) between the source/drain regions and the substrate as well as an increase in source/drain leakage current.

Double gate FETs have been used to address some of the disadvantages discussed above with reference to planar transistors. Double gate FETs can include two gate electrodes located on both sides of the channel region. Accordingly, the “on” current of the double gate FETs can be twice that of the planar transistors, which may increase the operating speed of the double gate FET compared to an equivalent planar transistor. However, some double gate FETs may still have the disadvantages of junction capacitance, source/drain leakage current, and complexity of fabrication processes discussed above.

Fin FETs have been used to address some of the complexities associated with double gate FETs. Fin FETs can be formed by etching a silicon substrate to form a protruding silicon fin and forming a gate electrode that crosses over the silicon fin. Accordingly, the fin FET may exhibit an “on” current that is almost equal to some double gate FETs, since the gate electrode of the fin FET in on both sidewalls of the silicon fin (i.e., both sides of the channel).

Methods of forming multi-fin FETs can include etching a silicon substrate to form a plurality of protruding silicon fins. In this approach, the widths of the fins may be non-uniform throughout the substrate due to limitations inherent in a photolithography process. In addition, the etching process may damage sidewalls of the fins. Also, there may be limitations, in this approach, to the degree to which the spacing between the fins may be reduced, as the spacing may depend upon the resolution of the photolithography process. Fin FETs are discussed, for example, in U.S. Pat. No. 6,413,802 to Hu et al. entitled FinFET Transistor Structures Having Double Gate Channel Extending Vertically From a Substrate and Methods of Manufacture.

### SUMMARY

Embodiments according to the present invention can provide methods of forming multi fin Field Effect Transistors (FET) using sacrificial fins and devices so formed. Pursuant to these embodiments, multi fin FETs can be formed by forming a first fin having opposing sidewalls protruding from a substrate and epitaxially growing second fins on the opposing sidewalls, where the second fins have respective exposed sidewalls protruding from the substrate. The second fins or the first fin can be removed to provide at least one fin for a multi fin FET.

In some embodiments according to the invention, a first fin can be formed having opposing sidewalls protruding from a substrate. Sacrificial fins are formed on the opposing sidewalls, where the sacrificial fins having respective exposed sidewalls protruding from the substrate. Then, a second fin can be formed protruding from the substrate on one of the respective exposed sidewalls. The sacrificial fins can then be removed.

In some embodiments according to the invention, forming at least a second fin protruding from the substrate can include forming second and third fins protruding from the substrate on respective ones of the exposed sidewalls. In some embodiments according to the invention, the sacrificial fins can be removed to provide an odd number of fins protruding from the substrate. In some embodiments according to the invention, a thermal oxide layer can be formed between the first and second fins on the sidewalls thereof to cover lower sidewall portions thereof and to provide exposed upper sidewall portions thereof. An insulating layer can be formed between the first and second fins on the lower sidewall portions and not on the exposed upper sidewall portions.

In some embodiments according to the invention, a gate insulating layer can be formed on the exposed upper sidewall portions of the first and second fins and a gate electrode can be formed on the first, second, and third fins. In some embodiments according to the invention, removing the sacrificial fins can be preceded by forming a first insulating layer on the substrate. Removing the sacrificial fins can also include etching the first insulating layer to a height above the substrate, forming a thermal oxide layer between the first and second fins on the sidewalls thereof, forming a second insulating layer on the first insulating layer and on the thermal oxide layer, and removing the second insulating layer and the thermal oxide layer from between the first and second fins so that a lower sidewall portion of the first and second fins remains covered below the height and is exposed above the height.

In some embodiments according to the invention, forming the sacrificial fins can include epitaxially growing the sacrificial fins, wherein the fins are separated by a distance that is less than a resolution of a photolithography process used to form the fins.

In some embodiments according to the invention, multi fin FETs can be formed by etching a semiconductor substrate to form a first silicon fin, sequentially forming sacrificial fins and second silicon fins on both sidewalls of the first silicon fin, and removing the sacrificial fins.

In some embodiments according to the invention, multi fin FETs can be formed by etching a silicon germanium layer on a substrate to form a sacrificial fin protruding from the substrate, where the sacrificial fin has opposing sidewalls, epitaxially growing fins on the opposing sidewalls of the sacrificial fin, and removing the sacrificial fin from between the epixatially grown fins to provide first and second fins for a multi fin FET.

In some embodiments according to the invention, multi fin FETs can include a plurality silicon fins protruding from a substrate, a first insulating layer pattern covering lower portions of outer sidewalls of outer silicon fins of the plurality of silicon fins, second insulating layer patterns filling regions between the silicon fins, the second insulating layer patterns formed to a level about equal to that of the first insulating layer pattern, a gate insulating layer formed on the silicon fins protruding from the first and second insulating layer patterns, and a gate electrode formed on the gate insulating layer.

### BRIEF DESCRIPTION OF THE DRAWINGS

FIGS. 1 to 9 are cross sectional views to illustrate methods of fabricating multi-fin FETs according to some embodiments of the invention.

FIGS. 10 to 15 are cross sectional views to illustrate methods of fabricating multi-fin FETs according to some embodiments of the invention.

FIGS. 16 to 19 are cross sectional views to illustrate methods of fabricating multi-fin FETs according to some embodiments of the invention.

### DETAILED DESCRIPTION OF EMBODIMENTS ACCORDING TO THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments of the present invention are described herein with reference to cross-sectional schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

It will further be understood that embodiments according to the invention can include any type of transistor formed as part of an integrated circuit device, such as a static random access memory (SRAM) device or a Large Scale Integrated (LSI) circuit device (such as a System-On a-Chip).

FIGS. 9 and 15 are vertical cross-sectional views, taken along a line crossing a channel region between source and drain regions (not shown), to illustrate multi fin FETs according to some embodiments of the invention. As shown in FIGS. 9 and 15, fin FETs according to some embodiments of the invention include a plurality of silicon fins that protrude from a substrate 100. For example, an odd number of silicon fins 120, 180L and 180R may be provided on the substrate 100 as shown in FIG. 9.

In some embodiments according to the invention, two outer silicon fins 180L and 180R are provided on the substrate 100 as shown in FIG. 15. A first insulating layer 200a is disposed on the substrate 100 outside the fin area. The first insulating layer 200a covers lower portions of outer sidewalls of the outer silicon fins 180L and 180R. Lower portions of gap regions between the silicon fins are filled with a second insulating layer 260a. In some embodiments according to the invention, the second insulating layer 260a has an etching selectivity with respect to the first insulating layer 200a. For example, in some embodiments according to the invention, when the first insulating layer 200a is a silicon oxide layer, the second insulating layer 260a may be a silicon nitride layer. In some embodiments according to the invention, a thermal oxide layer 240a is located between the second insulating layer 260a and the silicon fins 120, 180L and 180R (or 180L and 180R). In some embodiments according to the invention, an upper portion of the second insulating layer 260a is formed to the same height or level as that of the first insulating layer 200a. The silicon fins are covered with a gate insulating layer 280 and a gate electrode 300 is disposed on the silicon fins.

Accordingly, in some embodiments according to the invention, the distances between the silicon fins may be less than the widths of the silicon fins. In some embodiments according to the invention, the widths of the silicon fins may be less than a resolution limit of a photolithography process. In some embodiments according to the invention, the distances between the silicon fins may be equal to or less than the widths of the silicon fins.

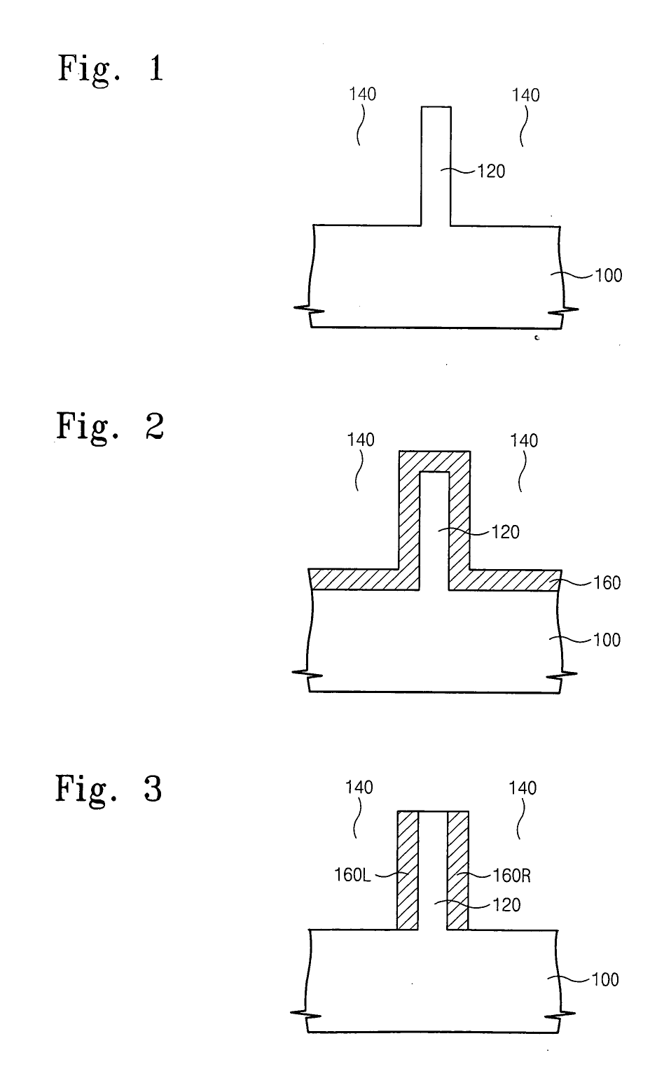

Methods of fabricating fin FETs according to some embodiments of the invention are described with reference to FIGS. 1 to 9. Referring to FIG. 1, a substrate 100, such as a silicon substrate, is etched to form a first silicon fin 120 having opposing sidewalls that protrude from the substrate 100. The etched region of the substrate 100 corresponds to a trench region 140. Although embodiments according to the invention are described herein with reference to silicon fins, it will be understood that the invention can be practiced with other materials.

Referring to FIG. 2, a sacrificial layer 160 is formed on the substrate and on the opposing sidewalls of the first silicon fin 120 using an epitaxial growth technique. In some embodiments according to the invention where the sacrificial layer 160 is formed using epitaxial growth, the sacrificial layer 160 may have a substantially uniform thickness that is less than a resolution associated with a photolithography process used to form the multi fin FET device. In some embodiments according to the invention, the thickness of the epitaxially formed sacrificial layer 160 defines a distance between immediately adjacent fins of the multi fin FET. Thus, the distance between the fins can be adjusted by controlling the thickness of the sacrificial layer 160.

In some embodiments according to the invention, the epitaxial sacrificial layer 160 is a layer that has the same crystalline structure and lattice constant as the substrate (such as silicon) and has an etching selectivity with respect to the first fin 120 and any additional silicon fins subsequently formed. For example, in some embodiments according to the invention, the epitaxial sacrificial layer 160 may be formed of a silicon germanium (SiGe) layer, a cesium oxide (CeO₂) layer and/or a calcium fluoride (CaF₂) layer.

Referring to FIG. 3, the sacrificial layer 160 is etched back to form sacrificial fins 160L and 160R that cover the opposing sidewalls of the first fin 120. The sacrificial fins 160L and 160R include exposed sidewalls. As described above, the sacrificial fins 160L and 160R may have a substantially uniform thickness that is less than a resolution associated with a photolithography process used to form the multi fin FET device.

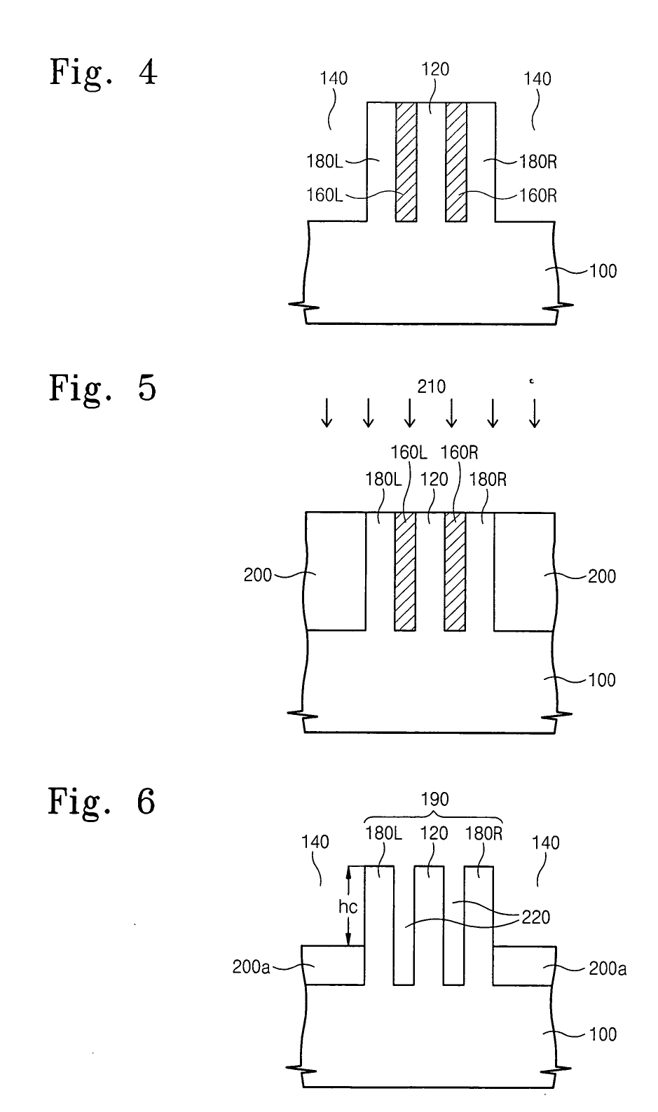

Referring to FIG. 4, a silicon layer is conformably formed on the sacrificial fins 160L and 160R and on the exposed sidewalls thereof. The conformal silicon layer is preferably formed using an epitaxial growth technique. The epitaxial silicon layer is then etched back to form second silicon fins 180L and 180R that cover the exposed sidewalls of the sacrificial fins 160L and 160R respectively. The widths of the second silicon fins 180L and 180R may be substantially uniform, since the silicon layer may be epitaxially grown, as described above.

In some embodiments according to the invention, additional fins may be formed by repeatedly forming sacrificial fins (analogous to 160L and 160R) and silicon fins thereon (such as silicon fins 180L and 180R) as described above in reference to FIGS. 2-4.

Referring to FIG. 5, an insulating layer is formed on the second silicon fins 180L and 180R and on the substrate 100. The insulating layer is planarized to expose upper surfaces of the sacrificial fins 160L and 160R. As a result, the trench region 140 is filled with a first insulating layer 200 that corresponds to the planarized insulating layer. In some embodiments according to the invention, the first insulating layer 200 is formed of a silicon oxide layer using a thin film deposition technique. In some embodiments according to the invention, the first insulating layer 200 is a silicon oxide layer that exhibits good step coverage.

An ion implantation process 210 is applied to the first silicon fin 120 and the second silicon fins 180L and 180R to dope the fins to provide a channel during operation of the multi fin FET. According to some embodiments of the invention, the sacrificial fins 160L and 160R may protect the underlying substrate 100 between the silicon fins 120, 180L and 180R from the channel ion implantation process 210. Thus, the implantation of ions into the substrate 100 may be reduced (or prevented) during process 210, whereas the silicon fins 120, 180L and 180R may be doped to have a desired impurity concentration profile.

Referring to FIG. 6, in some embodiments according to the invention, the sacrificial fins 160L and 160R are removed to form recesses 220 between the fins. A portion of the first insulating layer 200 is removed to expose an upper portion of the outer sidewalls of fins 180L and 180R and to keep a lower portion the outer sidewalls covered beneath the first insulating layer 200.

In some embodiments according to the invention, the sacrificial fins 160L and 160R are removed after partially removing the first insulating layer 200 to expose the upper portion. In particular, the first insulating layer 200 is removed to a level (or height) h_{c} below the upper surface of the fins. As a result, a multi silicon fin 190 (including the first and second silicon fins 120, 180L and 180R) is formed protruding from the substrate 100. In this case, the height h_{c} can correspond to a channel length for the multi fin FET according to some embodiments of the invention. After partial removal of the first insulating layer, the sacrificial fins 160L and 160R are selectively removed.

The removal of the sacrificial fins 160L and 160R forms gap regions 220 between the silicon fins 120, 180L and 180R. The distance between the silicon fins 120, 180L and 180R can correspond to the width of the sacrificial fins 160L and 160R. If the sacrificial fins are formed using an epitaxial growth technique, the sacrificial fins may have a width that is less than a resolution limit of some photolithography processes. Thus, the distance between the silicon fins can be reduced to less than the resolution of such photolithography processes.

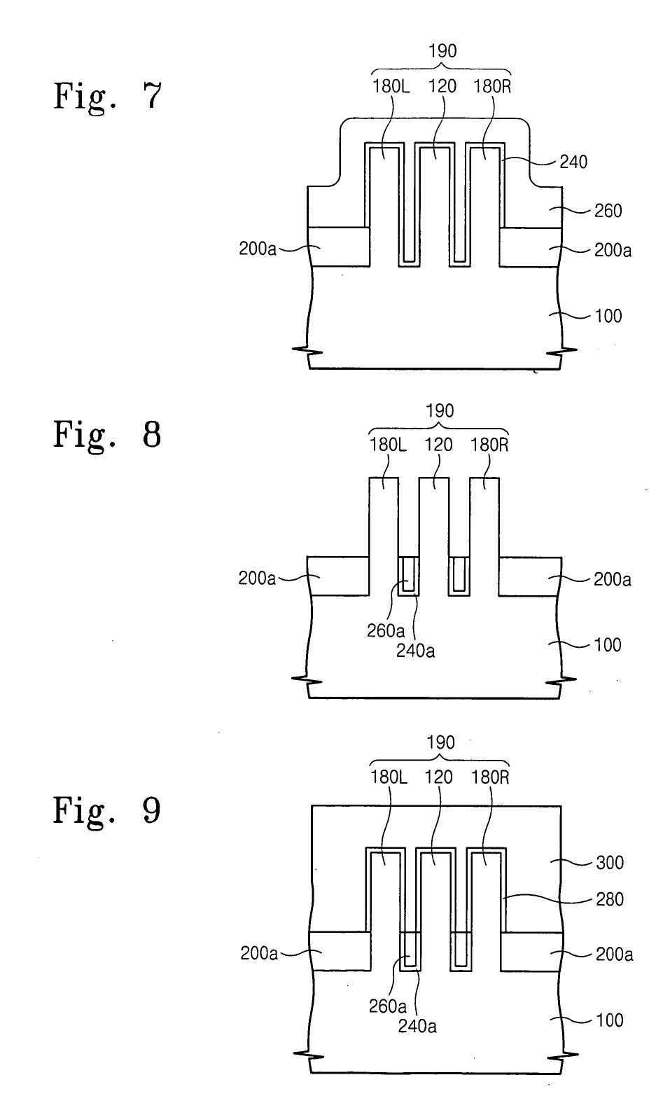

Referring to FIG. 7, a thermal oxide layer 240 is formed on sidewalls of the exposed silicon fins 120, 180L and 180R using a thermal oxidation technique. A second insulating layer 260 is formed on the thermal oxide layer 240 and on the first insulating layer pattern 200a. In some embodiments according to the invention, the second insulating layer 260 is formed to fill the gap regions 220. In some embodiments according to the invention, portions of the silicon fins are oxidized during formation of the thermal oxide layer 240. Thus, the width of the silicon fins after the thermal oxidation may be less than before the thermal oxidation. In some embodiments according to the invention, the second insulating layer 260 is a material layer having an etch selectivity with respect to the first insulating layer pattern 200a. For example, in some embodiments according to the invention, the second insulating layer 260 is a silicon nitride layer deposited using a thin film deposition technique.

Referring to FIG. 8, the second insulating layer 260 is partially etched to expose the upper portions of the sidewalls of the fins and leave a portion of the second insulating layer patterns 260a in the lower portions of the gap regions 220. In some embodiments according to the invention, the second insulating layer 260 is partially etched so that the second insulating layer pattern 260a in the gap regions is reduced to the same level as the first insulating layer pattern 200a on the outer sidewalls of the fins 180L and 180R.

The thermal oxide layer 240 on the protruding silicon fins is removed to leave a thermal oxide layer patterns 240a beneath the second insulating layer patterns 260a in the gap regions. In some embodiments according to the invention where the ion implantation 210 shown in FIG. 5 is skipped, the ion implantation process 210 may be performed after removal of the thermal oxide layer 240 from the protruding silicon fins described above in reference to FIG. 8. The first insulating layer pattern 200a can be exposed during formation of the second insulating layer patterns 260a. The first insulating layer pattern 200a and the second insulating layer patterns 260a may act as an isolation layer that electrically insulates the adjacent silicon fins from each other.

In some embodiments according to the invention, the thermal oxide layer 240 may not be formed. However, the formation of the thermal oxide layer 240 promote device integration density, since the thermal oxidation process can reduce the width of the silicon fins. Further, thermal oxide layer 240 may protect the underlying layers when the second insulating layer 260 is partially etched.

Referring to FIG. 9, a gate insulating layer 280 is formed on the exposed portions of the silicon fins 120, 180L and 180R. A gate electrode 300 is formed on the gate insulating layer 280 on the silicon fins including in the gap regions therebetween. In some embodiments according to the invention, the gate insulating layer is formed by thermally oxidizing the silicon fins 120, 180L and 180R. Accordingly, an odd number of silicon fins (such as three) can be are formed.

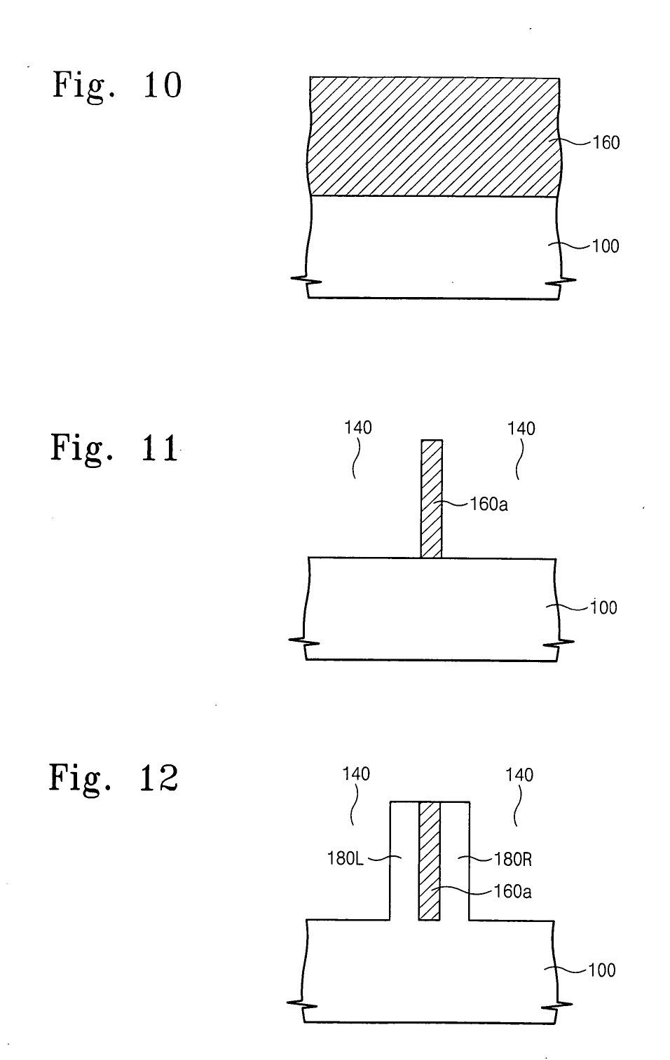

FIGS. 10 to 15 are vertical sectional views, taken along a line crossing a channel region between source and drain regions (not shown), to illustrate methods of forming multi fin FETs according to some embodiments of the invention. Referring to FIG. 10, a sacrificial layer 160 is formed on a substrate 100. In some embodiments according to the invention, the substrate 100 is a silicon substrate and the sacrificial layer 160 is a silicon germanium (SiGe) layer. In some embodiments according to the invention, the sacrificial layer 160 is formed using an epitaxial growth technique.

Referring to FIG. 11, the sacrificial epitaxial layer 160 is patterned to form a sacrificial SiGe fin 160a, or sacrificial fin structure. The etched region of the sacrificial layer 160 provides a trench region 140.

Referring to FIG. 12, silicon fins 180L and 180R are formed on opposing sidewalls of the sacrificial fin 160a respectively. In some embodiments according to the invention, the silicon fins 180L and 180R are formed by growing an epitaxial silicon layer on the substrate 100 and on the opposing sidewalls of the sacrificial fin 160a and etching back the epitaxial silicon layer.

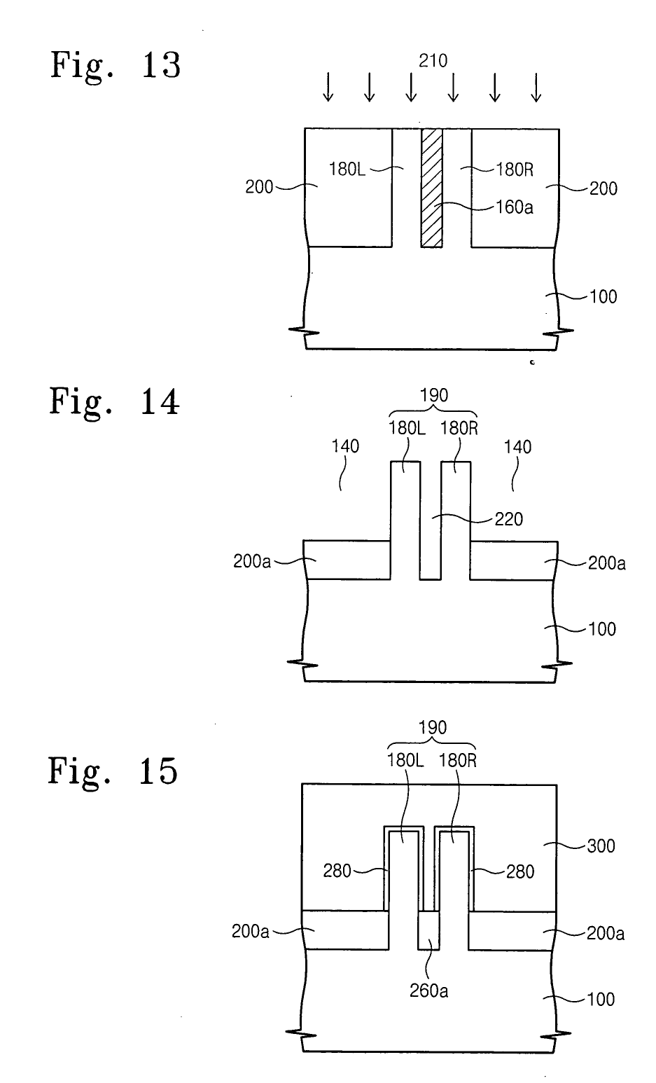

Referring to FIG. 13, an insulating layer is formed on the substrate 100 and on exposed sidewalls of the silicon fins 180L and 180R. The insulating layer is planarized until upper surfaces of the sacrificial fin 160a and the silicon fins 180L and 180R are exposed, thereby forming a first insulating layer 200 that fills the trench region 140. In some embodiments according to the invention, the first insulating layer 200 is a silicon oxide layer.

A desired number of fins can be made by forming additional sacrificial fins (as described above in reference to FIGS. 11-14 prior to formation of the first insulating layer 200. In some embodiments according to the invention, an ion implantation process 210 is applied to the silicon fins 180L and 180R after planarization of the insulating layer.

Referring to FIG. 14, the first insulating layer 200 is partially etched to lower the surface level thereof and expose an upper portion of the sidewalls of the fins 180L and 180R and to leave a lower portion of the sidewalls of the fins 180L and 180R covered. As a result, a second insulating layer pattern 200a fills a lower portion of the trench region 140. The sacrificial fin 160a is removed to provide a gap region 220 between the silicon fins 180L and 180R to form a multi silicon fin 190 including the silicon fins 180L and 180R protruding from the substrate 100. In some embodiments according to the invention, the first insulating layer 200 is partially etched after removal of the sacrificial fin 160a.

Referring to FIG. 15, an insulating layer is formed on the first insulating layer pattern 200a and in the gap region 220. In some embodiments according to the invention, the insulating layer is formed to completely fill the gap region 220. The insulating layer is partially etched to form a second insulating layer pattern 260a that remains in the lower portion of the gap region 220.

In some embodiments according to the invention, the insulating layer is partially etched so that the second insulating layer pattern 260a has the same level as the first insulating layer pattern 200a outside the gap region 220. In some embodiments according to the invention, the second insulating layer pattern 260a is a silicon nitride layer. A gate insulating layer 280 and a gate electrode 300 are formed on the firsty and second fins 180L and 18-R using as described above, for example, in reference to FIG. 9. Accordingly, an even number (such as two) of silicon fins are formed.

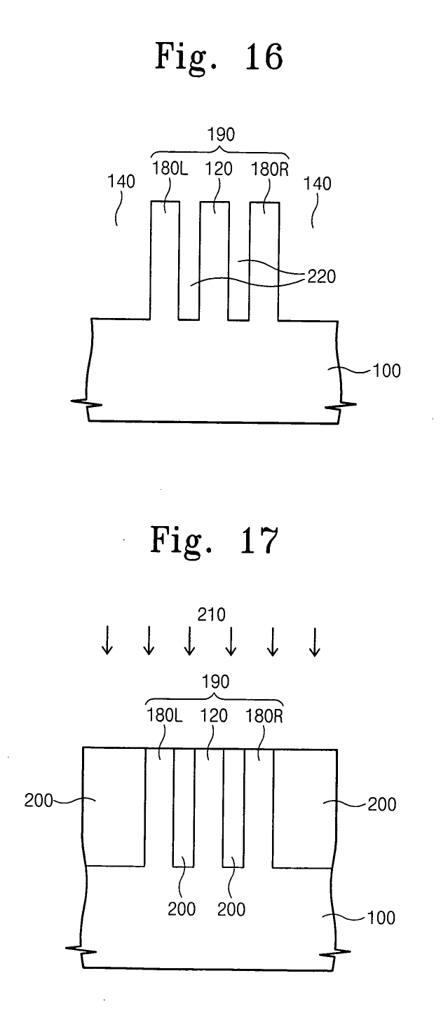

FIGS. 16 to 19 are vertical cross-sectional views, taken along a line crossing a channel region between source and drain regions (not shown), to illustrate methods of forming multi fin FETs according to some embodiments of the invention. Referring to FIG. 16, a first silicon fin 120, a trench region 140, second silicon fins 180L and 180R, and sacrificial fins (not shown) are formed, for example, as described above with reference to FIGS. 1 to 4, although other techniques may be used. The sacrificial fins are removed to provide the gap regions 220 between the silicon fins. As a result, a multi silicon fin 190 is formed protruding from the substrate 100.

Referring to FIG. 17, an insulating layer is formed on the substrate 100, on the gap regions 220, and on the trench region 140. The insulating layer is planarized to expose an upper surface of the multi silicon fin 190. Thus, the gap regions 220 and the trench region 140 are filled with the planarized insulating layer, i.e., an insulating layer pattern 200. In some embodiments according to the invention, the insulating layer is formed of a material layer that exhibits good step coverage. An ion implantation process is applied to the silicon fins 120, 180L and 180R to provide a channel region that can be formed during operation of the multi fin FET.

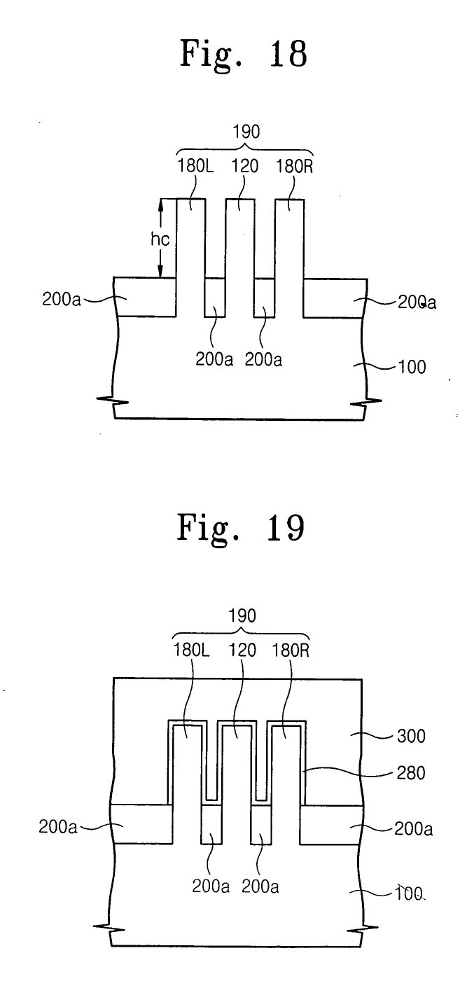

Referring to FIG. 18, the insulating layer pattern 200 on the substrate and in the gap regions 220 is partially etched to lower a surface level of the insulating layer pattern therein. As a result, the silicon fins 120, 180L and 180R protrude a height h_{c} beyond the insulating layer pattern 200a, which can correspond to a channel of the multi fin FET. Referring to FIG. 19, a gate insulating layer 280 and a gate electrode 300 are formed, for example, as described above with reference to FIG. 9.

As discussed above, a multi silicon fin can be formed using epitaxial growth which may promote controllable and a substantially uniform thickness for the fins included in the multi fin FET. In some embodiments according to the invention, the distances between the silicon fins may be less than the widths of the silicon fins. In some embodiments according to the invention, the widths of the silicon fins may be less than a resolution limit of a photolithography process. In some embodiments according to the invention, the distances between the silicon fins may be equal to or less than the widths of the silicon fins.

Many alterations and modifications may be made by those having ordinary skill in the art, given the benefit of present disclosure, without departing from the spirit and scope of the invention. Therefore, it must be understood that the illustrated embodiments have been set forth only for the purposes of example, and that it should not be taken as limiting the invention as defined by the following claims. The following claims are, therefore, to be read to include not only the combination of elements which are literally set forth but all equivalent elements for performing substantially the same function in substantially the same way to obtain substantially the same result. The claims are thus to be understood to include what is specifically illustrated and described above, what is conceptually equivalent, and also what incorporates the essential idea of the invention.

1. A method of forming a multi fin Field Effect Transistor (FET) comprising:
forming a first fin having opposing sidewalls protruding from a substrate;
epitaxially growing second fins on the opposing sidewalls, the second fins having respective exposed sidewalls protruding from the substrate; and
removing the second fins or the first fin to provide at least one fin for a multi fin FET.

2. A method of forming a multi fin Field Effect Transistor (FET) comprising:
forming a first fin having opposing sidewalls protruding from a substrate;
forming sacrificial fins on the opposing sidewalls, the sacrificial fins having respective exposed sidewalls protruding from the substrate; and then forming second fins protruding from the substrate on the respective exposed sidewalls; and
removing the sacrificial fins.

3. A method according to claim 2 further comprising forming additional sacrificial fins on respective sidewalls of the second fins and additional second fins on respective sidewalls of the additional sacrificial fins;
wherein forming the additional sacrificial fins and the additional second fins are repeated at least one time; and
wherein removing the sacrificial fins further removing the additional sacrificial fins.

4. A method according to claim 3 wherein removing the sacrificial fins comprises removing the sacrificial fins and the additional sacrificial fins to provide an odd number of fins protruding from the substrate.

5. A method according to claim 2 further comprising:
forming a thermal oxide layer between the first and second fins on the sidewalls thereof to cover lower sidewall portions thereof and to provide exposed upper sidewall portions thereof; and
forming an insulating layer between the first and second fins on the lower sidewall portions and not on the exposed upper sidewall portions.

6. A method according to claim 5 further comprising:
forming a gate insulating layer on the exposed upper sidewall portions of the first and second fins; and
forming a gate electrode on the first, second, and third fins.

7. A method according to claim 3 wherein removing the sacrificial fins is preceded by forming a first insulating layer on the substrate, wherein removing the sacrificial fins further comprises:
etching the first insulating layer to a height above the substrate;
forming a thermal oxide layer between the first and second fins on the sidewalls thereof;
forming a second insulating layer on the first insulating layer and on the thermal oxide layer;
removing the second insulating layer and the thermal oxide layer from between the first and second fins so that a lower sidewall portion of the first and second fins remains covered below the height and is exposed above the height.

8. A method according to claim 2 wherein forming sacrificial fins comprises epitaxially growing the sacrificial fins, wherein the fins are separated by a distance that is less than a resolution of a photolithography process used to form the fins.

9. A method of fabricating a multi fin field effect transistor, the method comprising:
etching a semiconductor substrate to form a first silicon fin;
sequentially forming sacrificial fins and second silicon fins on both sidewalls of the first silicon fin; and
removing the sacrificial fins.

10. A method of forming a multi fin Field Effect Transistor (FET) comprising:
etching a silicon germanium layer on a substrate to form a sacrificial fin protruding from the substrate having opposing sidewalls;
epitaxially growing fins on the opposing sidewalls of the sacrificial fin; and
removing the sacrificial fin from between the epixatially grown fins to provide first and second fins for a multi fin FET.

11. A method according to claim 10 wherein removing the sacrificial fin from between the epixatially grown fins is preceded by forming a first insulating layer on the substrate and on the epixatially grown fins and on the sacrificial fin, wherein removing the sacrificial fin further comprises:
removing the sacrificial fin from between the epixatially grown fins to provide the first and second fins having a recess therebetween; and
removing a portion the first insulating layer to provide a remaining portion of the first insulating layer on the substrate outside the recess having a height above the substrate.

12. A method according to claim 11 further comprising:
forming a second insulating layer in the recess to the height about equal to the remaining portion of the first insulating layer to provide exposed upper portions of the first and second fins uncovered by the first and second insulating layers.

13. A method according to claim 12 further comprising:
forming a gate insulating layer on the exposed upper portions.

14. A method according to claim 13 further comprising:
forming a gate electrode on the first and second fins to provide multiple fins for the multi fin FET.

15. A method according to claim 12 further comprising:
forming a thermal oxide layer on the first and second fins prior to formation of the second insulating layer; and
removing the thermal oxide layer after partially etching the second insulating layer.

16. A method according to claim 11 wherein the first insulating layer comprises a silicon oxide layer and the second insulating layer comprises a silicon nitride layer.

17. A method according to claim 10 further comprising:
implanting ions into the first and second fins prior to removal of the sacrificial fin.

18. A multi fin field effect transistor (FET) comprising:
a plurality silicon fins protruding from a substrate;
a first insulating layer pattern covering lower portions of outer sidewalls of outer silicon fins of the plurality of silicon fins;
a second insulating layer patterns filling regions between the silicon fins, the second insulating layer patterns formed to a level about equal to that of the first insulating layer pattern;
a gate insulating layer formed on the silicon fins protruding from the first and second insulating layer patterns; and
a gate electrode formed on the gate insulating layer.

19. A multi fin FET according to claim 18 wherein the first insulating layer pattern comprises a silicon oxide layer and the second insulating layer comprises a silicon nitride layer.

20. A multi fin FET according to claim 18 further comprising:
a thermal oxide layer under the second insulating layer pattern.
